(19) United States
(12) Patent Application Publication
(10) Pub. No.: US 2011/0202817 A1
(43) Pub. Date: Aug. 18, 2011

(54) NODE INFORMATION STORAGE METHOD AND SYSTEM FOR A LOW-DENSITY PARITY-CHECK DECODER

(75) Inventors: Jianhao Hu, Chengdu (CN); Hong Wen, Chengdu (CN); Ding Li, Chengdu (CN); Feng Li, Chengdu (CN)

(73) Assignee: NXP B.V., Eindhoven (NL)

(21) Appl. No.: 13/000,262

(22) PCT Filed: Jun. 18, 2009
(86) PCT No.: PCT/IB2009/052592

§ 371 Date: Mar. 25, 2011

(30) Foreign Application Priority Data
Jun. 18, 2008 (US) 61073433

(51) Int. Cl. H03M 13/05; G06F 11/10

(52) U.S. Cl. 714/763; 714/E11.034

(57) ABSTRACT

A receiver to receive a signal associated with a low-density parity-check (LDPC) code. The receiver includes a memory device, an address generator, and an LDPC decoder. The LDPC decoder includes a row designator and a position designator. The memory device stores data related to an LDPC decoding process. The address generator generates an access address to the stored data. The LDPC decoder performs the LDPC decoding process. The row designator designates a row from a parity-check matrix as a parent row and designates a plurality of corresponding rows from the parity-check matrix as child rows. The position designator designates an original position order of each parent non-zero element of 10 the parent row according to an actual position order of each parent non-zero element in the parent row. The actual position order includes a numerical order of the parent non-zero elements.

In information theory, a low-density parity-check (LDPC) code, or Gallager code, is an error correcting code. LDPC encoding is a method of transmitting a message over a noisy transmission channel. LDPC codes allow data transmission rates to approach the theoretical maximum of transmitting a message over a noisy transmission channel called the Shannon Limit. LDPC codes are defined by a sparse parity-check matrix, a matrix populated primarily with zeros. This sparse matrix is often randomly generated and may be subject to sparsity constraints.

LDPC code is a block code described with a binary sparse M×N parity-check matrix H. Each row, M, of the matrix H corresponds to a parity check, and each column, N, represents a demodulated symbol. The number of non-zero elements in each row or column may be referred to as a row weight or a column weight, respectively. The LDPC code with uniform row weight and column weight is called a regular code. Otherwise it is an irregular code. An LDPC code is considered (j, k)-regular if every variable node has an equal degree of j check node connections per variable node and every check node has an equal degree of k variable node connections per check node.

An exemplary parity-check matrix H of an LDPC code of length N=10 and dimension M=5 is given by:

$$H = ( \begin{matrix}0 & 0 & 1 & 1 & 0 & 0 & 1 & 0 & 1 & 0 \\ 1 & 0 & 0 & 1 & 0 & 1 & 0 & 0 & 0 & 1 \\ 1 & 0 & 1 & 0 & 1 & 0 & 0 & 1 & 0 & 0 \\ 0 & 1 & 0 & 0 & 1 & 1 & 0 & 0 & 1 & 0 \\ 0 & 1 & 0 & 0 & 0 & 0 & 1 & 1 & 0 & 1\end{matrix} )$$

where there are two is per column, or per variable node, and there are four is per row, or per check node. The leftmost side of any row in the parity-check matrix H is the start of an LDPC code, and the rightmost side of any row is the end of an LDPC code. As shown in the matrix H, the two 1 s per column means that there are two edge connections per variable node, and the four is per row means that there are four edge connections per check node.

A Tanner graph is a bipartite graph, a graph whose vertices are divided into disjoint sets. An LDPC code may be represented by a Tanner graph between N nodes on one side called variable (or message) nodes corresponding to a set of code-words and M nodes on another side called check (or constraint) nodes corresponding to the set of parity check constraints. Each edge corresponds to a non-zero entry in the parity check matrix. The node information is stored and updated during an iterative LDPC decoding procedure.

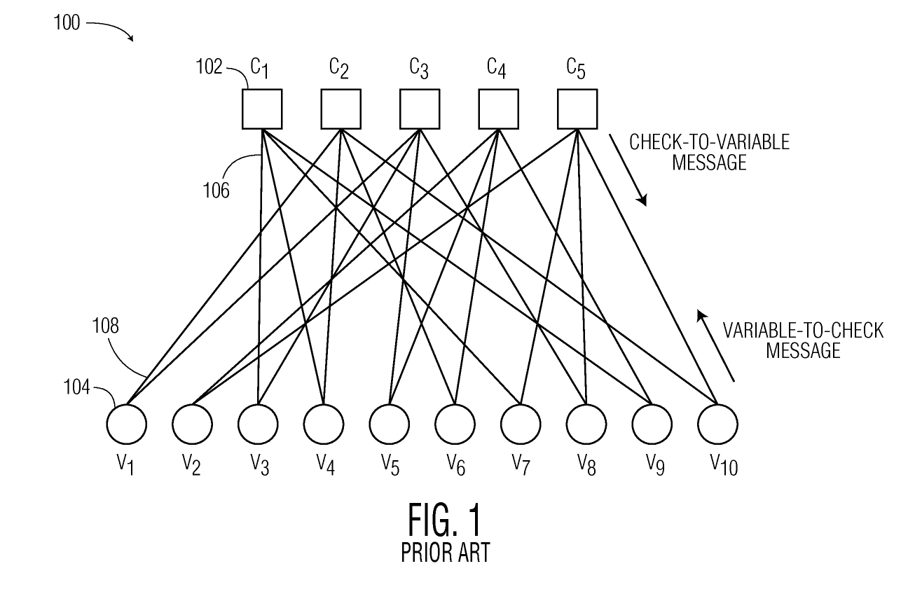

FIG. 1 depicts a conventional Tanner graph 100. The depicted conventional Tanner graph 100 of FIG. 1 corresponds to the exemplary parity-check matrix H of an LDPC code of length N=10 and dimension M=5 described above. The conventional Tanner graph 100 includes check nodes 102, variable nodes 104, check-to-variable messages 106, and variable-to-check messages 108.

A one in the parity-check matrix in row j, j=1, . . . M and in column i, i=1, . . . N represents an edge connection between the i-th variable node vᵢ and the j-th check node cⱼ. The number of edges incident to the i-th variable node vᵢ is called the variable node degree d(vᵢ) which is equal to the number of ones in column i. Similarly, the number of edges connected with the j-th check node cⱼ is called the check node degree d(cⱼ), and is equal to the number of ones in row j. As depicted in FIG. 1, each variable node 104 has a column weight or degree of d(vᵢ)=2 that corresponds to the number of edge connections on each variable node 104. Additionally, every check node 102 has a row weight or degree of d(cⱼ)=4 that corresponds to the number of edge connections on each check node 102. Thus, FIG. 1 depicts a (2, 4)-regular LDPC code. In coding theory, a parity-check matrix of a linear block code C is a generator matrix of the dual of the code. As such, a codeword c is in C if and only if the matrix-vector product H·c=0.

LDPC codes can be effectively decoded by an iterative belief-propagation (BP) algorithm, also known as a sum-product algorithm. The structure of the BP decoding algorithm directly matches the constraints of the conventional Tanner graph 100. Decoding of a message is computed on each conventional variable node 104 and each conventional check node 102 and iteratively communicated through the edge connections between neighboring nodes. During the decoding, belief messages are exchanged along the edge connections, and the information of variable and check nodes is updated.

Generally, LDPC decoder hardware implementations use a fixed-point method. Since the non-linear functions are used in calculation of the BP algorithm, the implementation complexity is relatively high. Conventional decoding systems may use a Very Large Scale Integration (VLSI) solution to decode an LDPC block code. However, typical VLSI solutions may cause message congestion between the check nodes and variable nodes due to routing congestion, especially for the irregular LDPC. Additionally, typical VLSI solutions may cause data congestion due to attempts to simultaneously access the information of the same node.

Embodiments of a system are described. In one embodiment, the system is a receiver to receive a signal associated with a low-density parity-check (LDPC) code. The receiver includes a memory device, an address generator, and an LDPC decoder. The LDPC decoder includes a row designator and a position designator. The memory device stores data related to an LDPC decoding process. The address generator generates an access address to the stored data. The LDPC decoder performs the LDPC decoding process. The row designator designates a row from a parity-check matrix as a parent row and designates a plurality of corresponding rows from the parity-check matrix as child rows. The position designator designates an original position order of each parent non-zero element of the parent row according to an actual position order of each parent non-zero element in the parent row. The actual position order includes a numerical order of the parent non-zero elements. Other embodiments of the system are also described.

Embodiments of an LDPC decoding method are also described. In one embodiment, the method is a method for decoding LDPC codes. The method includes storing data related to an LDPC decoding process. The method also includes generating an access address to the stored data. The method also includes designating a row from a parity-check matrix as a parent row. The method also includes designating a plurality of corresponding rows from the parity-check matrix as child rows. The method also includes designating an original position order of each parent non-zero element of the parent row according to an actual position order of each parent non-zero element in the parent row. The actual position order includes a numerical order of the parent non-zero elements. Other embodiments of the method are also described.

Other aspects and advantages of embodiments of the present invention will become apparent from the following detailed description, taken in conjunction with the accompanying drawings, illustrated by way of example of the principles of the invention.

FIG. 1 depicts a conventional Tanner graph.

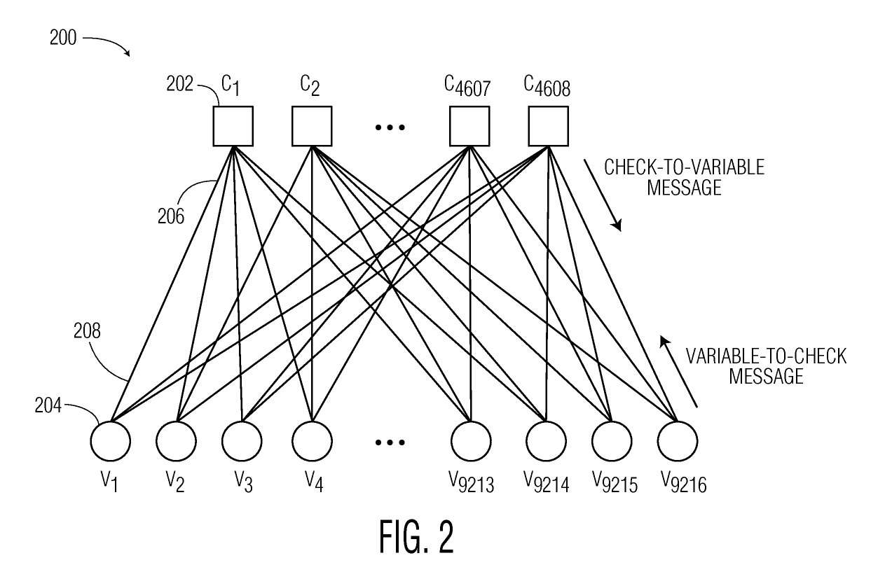

FIG. 2 depicts a Tanner graph for the Satellite-Terrestrial interactive Multi-service infrastructure (STiMi).

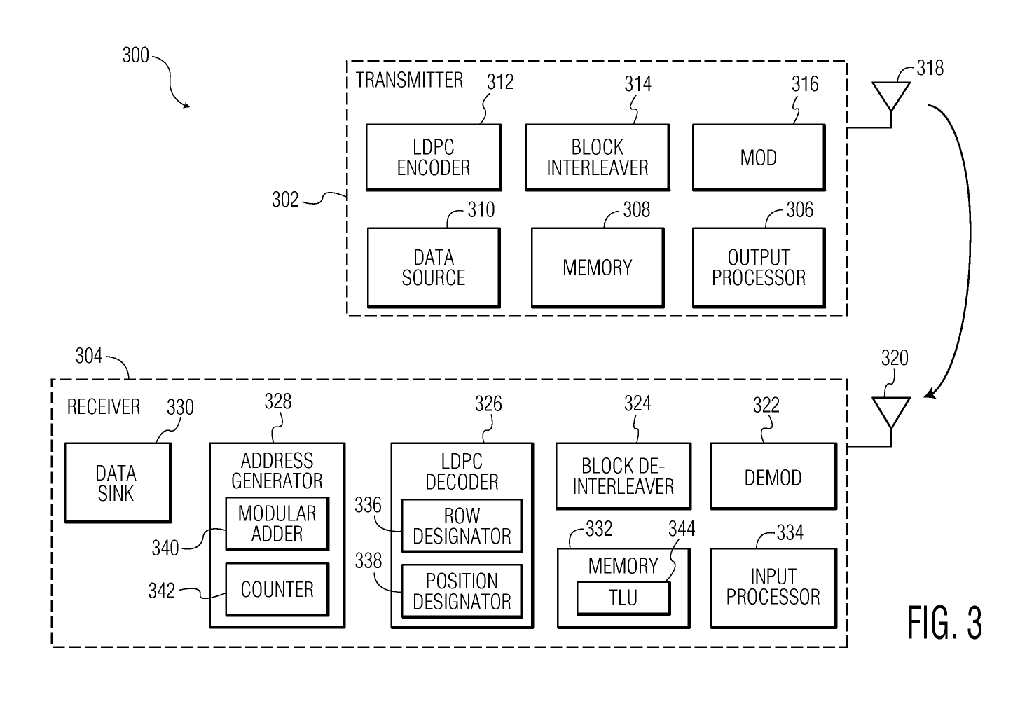

FIG. 3 depicts a schematic block diagram of one embodiment of a low-density parity-check (LDPC) system.

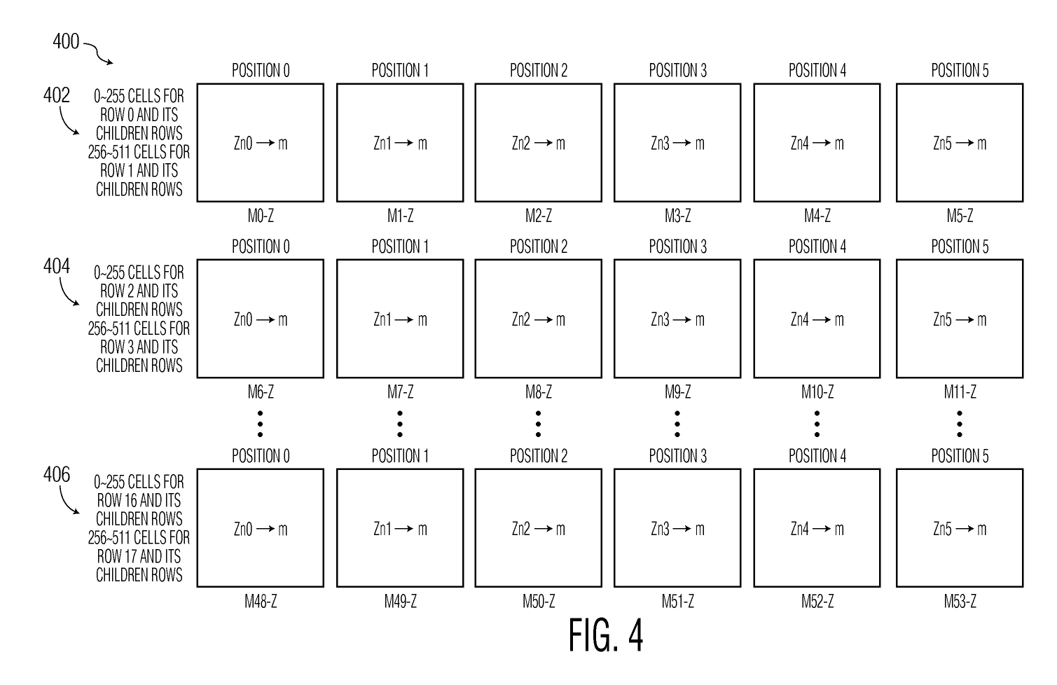

FIG. 4 depicts a schematic block diagram of one embodiment of a variable node information storage scheme for use with the LDPC decoder of FIG. 3.

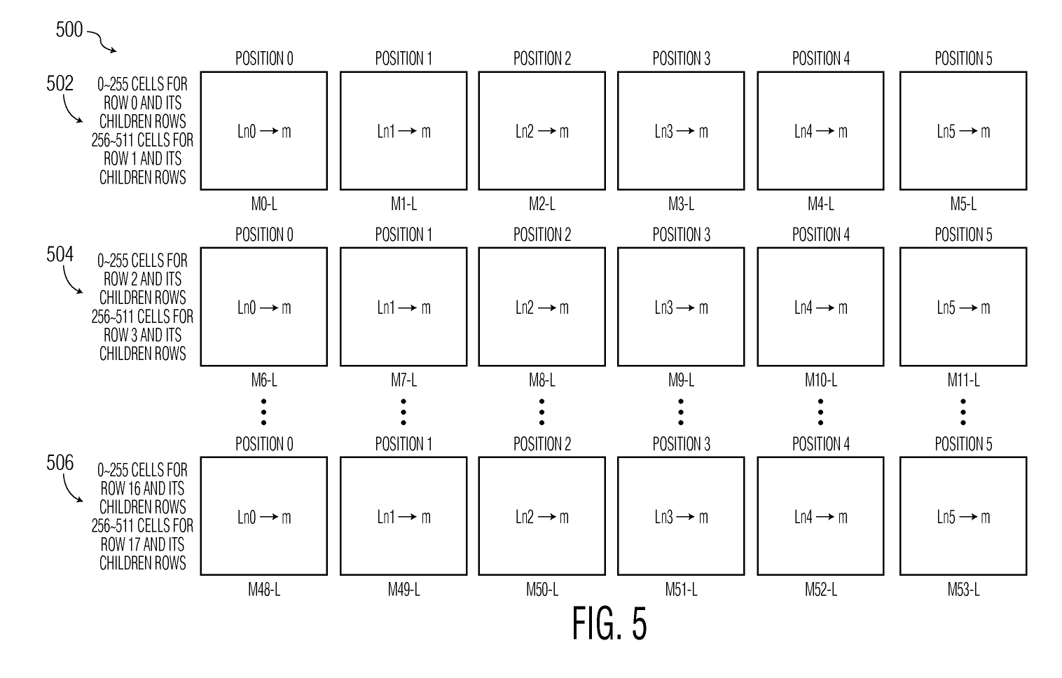

FIG. 5 depicts a schematic block diagram of one embodiment of a check node information storage scheme for use with the LDPC decoder of FIG. 3.

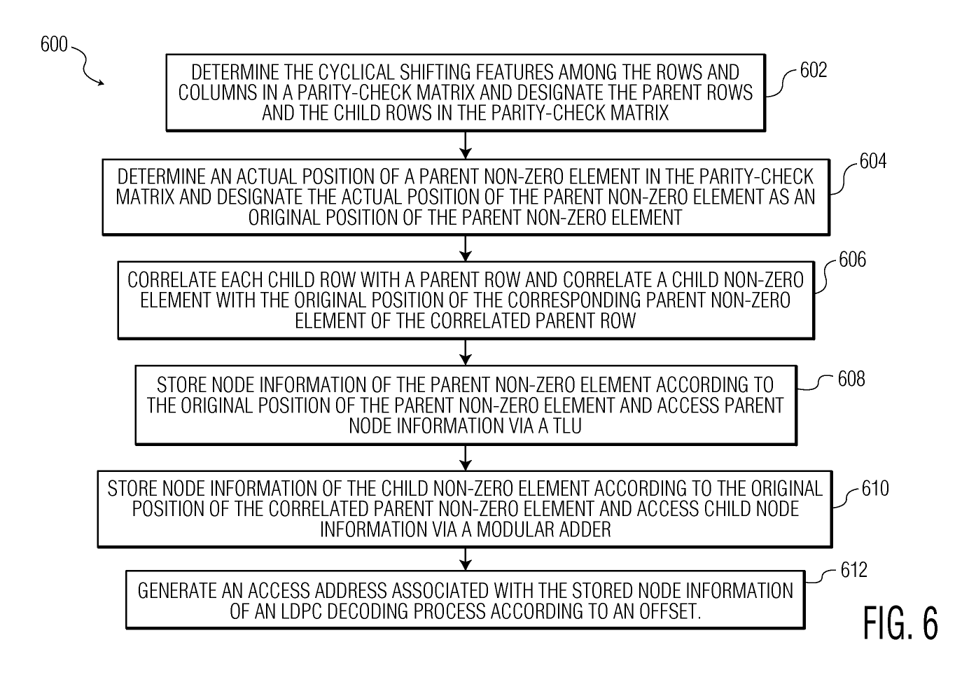

FIG. 6 depicts a schematic flow chart diagram of one embodiment of a node information storage method for use with the modular adder of FIG. 3.

Throughout the description, similar reference numbers may be used to identify similar elements.

FIG. 2 depicts a Tanner graph for the Satellite-Terrestrial interactive Multi-service infrastructure (STiMi). STiMi specifies LDPC codes for satellite transmission. The depicted STiMi Tanner graph 200 includes STiMi check nodes 202, STiMi variable nodes 204, STiMi check-to-variable messages 206, and STiMi variable-to-check messages 208.

The STiMi Tanner graph 200 of FIG. 2 corresponds to a parity-check matrix H of an LDPC code of length N=9,216 and dimension M=4,608, corresponding to a ½-rate. In the exemplary STiMi Tanner graph 200, there are three is per column and six is per row. Thus, there are three edge connections per variable node with 9,216 total variable nodes and six edge connections per check node with 4,608 total check nodes for a ½-rate. Likewise, for a ¾-rate (not shown) there are three edge connections per variable node with 9,216 total variable nodes and twelve edge connections per check node with 2,304 total check nodes. In FIG. 2, the edge connections for the STiMi example are shown for exemplary illustration purposes only. Actual edge connections between certain STiMi variable nodes 204 and certain STiMi check nodes 202 may be implemented with different connections than as depicted in FIG. 2.

In an LDPC decoding process, the decoding operations include the local application of Bayes' theorem at each node and the exchange of the messages or results with neighboring nodes. At any given iteration, two types of messages are passed—probabilities or “beliefs” from symbol nodes to check nodes, and probabilities or “beliefs” from check nodes to symbol nodes. The framework of the iterative belief-propagation (BP) algorithm is shown in the STiMi Tanner graph 200 of FIG. 2. In one embodiment, an original position node information storage (OPNS) process is used in conjunction with a BP algorithm. In some embodiments, OPNS is used in conjunction with a BP-based algorithm and/or a modification of the BP-based algorithm.

Let M(n) denote the set of check nodes connected to variable nodes n, e.g., the positions of ones in the n-th column of H, and let N(m) denote the set of variable nodes that participate in the m-th parity-check equation, e.g., the positions of ones in the m-th row of H. N(m)\n represents the exclusion of n from the set N(m). M(n)\m represents the exclusion of m from the set M(n). In addition, qₘₙ(0) and qₘₙ(1) denote the messages from variable node n to check node m, which indicate the probabilities of symbol n being zero and one, respectively, based on all the checks involving n except m. Similarly, rₘₙ(0) and rₘₙ(1) denote the message from the m-th check node to the n-th symbol node, which indicate the probability of symbol n being zero and one, respectively, based on all the variables checked by m except n. yₙ represents a word which is modulated by a receiver after transmission through an Additive White Gaussian Noise (AWGN) channel, and Fₙ is the initial information of a variable node.

$${Z}_{mn} ( {x}_{n} ) {=}^{def} log ( {q}_{mn} ( 0 ) / {q}_{mn} ( 1 ) ) , {L}_{mn} ( {x}_{n} ) {=}^{def} log ( {r}_{mn} ( 0 ) / {r}_{mn} ( 1 ) ) ,$$

and
x=[x₁, x₂, . . . , x_{N}] denote the transmitted codeword, and y=[y₁, y₂, . . . , y_{N}] denotes the received word.

During initialization, each variable node n is assigned an a posteriori log-likelihood ratio (LLR), according to the following:

L(xₙ|yₙ)=log(P(xₙ=0|yₙ)/P(xₙ=1|yₙ)

for every position (m, n) such that

$${H}_{m , n} = 1 , {z}_{mn} = {F}_{n} = 4 {y}_{n} \frac{{E}_{b}}{{N}_{0}} .$$

During the check-node update, for each m, and for each nεN(m):

$${L}_{mn} = 2 {tanh}^{- 1} ( {\prod }_{{n}^{′} ∈ N ( m ) / n} tanh ( {z}_{{mn}^{′}} / 2 ) )$$

where

$$tanh ( \frac{x}{2} ) = \frac{{e}^{x} - 1}{{e}^{x} + 1} .$$

During the variable node update, for each n:

$${z}_{mn} = {F}_{n} + {\sum }_{{m}^{′} ∈ M ( n ) \backslash m} {L}_{{m}^{′} n} ,$$

Finally, for each n:

$${z}_{n} = {F}_{n} + {\sum }_{m ∈ M ( n )} {L}_{mn}$$

A quantization of \hat{x}=[\hat{x}₁, \hat{x}₂, . . . , \hat{x}_{N}] may be used such that \hat{x}ₙ=0 if Zₙ(xₙ)<0, and \hat{x}ₙ=1 if Zₙ(xₙ)>0. If \hat{x}H^{T}=0, the process ends, with \hat{x} determined to be the decoded output. Otherwise the above computations may be repeated. If the algorithm does not halt within some iteration, a decoder failure may be declared.

For the BP-based algorithm, the check-node update step is replaced with:

$${L}_{mn} = {( - 1 )}^{\overline{{σ}_{m} ⊕ {σ}_{mn}}} {min}_{{n}^{′} ∈ N ( m ) \backslash n} \vert {z}_{{mn}^{′}} \vert .$$

In the STiMi example, the LDPC code has 2 code rates, ½ and ¾. The code length N is 9,216 bits. One specific configuration is listed in Table 1.

TABLE 1
LDPC code configuration.

| Data rate | Information bit length K | Code length N |
|---|---|---|
| 1/2 | 4,608 bits | 9,216 bits |
| 3/4 | 6,912 bits | 9,216 bits |

For the ½ rate STiMi example, the non-zero element position of the i-th row in the parity can be traced back to the its parent row with shifting parameter, s:

s=i mod 18.

If the non-zero is the j-th column in the parent row, the number of the position of this non-zero element in the child row, j′, can be computed by the following:

j′=j+s×36

The non-zero position in the parent rows, which is the i-th non-zero element in the row, is referred to as the original position. The node information of the child row is stored according to the original position order, no matter the actual position order. For example, there are six positions, position 0, position 1, position 2, position 3, position 4 and position 5, for the six non-zero elements in each row in the ½ rate STiMi parity-check matrix from the left to the right. In the STiMi parity-check matrix, the column of the sixth non-zero element, “F”, is in the 9189^{th} column of the 5^{th} row, or the fifth parent row. The 1^{st} non-zero element in the 22^{nd} row, the first child row of the 5^{th} row, is generated by “F”. According to the principle of OPNS, the variable and check nodes information for the 22^{nd} row is still stored in the 6^{th} position, position 5, in order to enable an iteration procedure using a modular adder and/or counter.

FIG. 3 depicts a schematic block diagram of one embodiment of a low-density parity-check (LDPC) system 300. The LDPC system 300 includes a transmitter 302 and a receiver 304. Although certain component parts are shown in conjunction with the LDPC system 300 of FIG. 3, other embodiments may include fewer or more component parts, or equivalent parts, to perform fewer or more LDPC node storage functions. Additionally, while the components of the LDPC system 300 are shown in FIG. 3 as being separate components, some of these components may be integrated. As an example, the components of the transmitter 302 and/or the components of the receiver 304 may be implemented in a single transceiver integrated circuit chip. Furthermore, some of the components of the LDPC system 300 may be implemented in a combination of software, hardware, and/or firmware.

As depicted in FIG. 3, the transmitter 302 includes an output processor 306, a transmitter memory device 308, a data source 310, an LDPC encoder 312, a block interleaver 314, a modulator 316, and at least one transmitter antenna 318. In general, the transmitter 302 transmits data to a receiver 304. In one embodiment, the transmitter is a base station (BS) in a terrestrial data network. In some embodiments, the transmitter is a satellite in orbit over the earth, transmitting data packets to a receiver 304 on earth. In some embodiments, the transmitter is a satellite transmitting data packets to another satellite, or some receiver 304, that is also in space and/or orbit. In some embodiments, the transmitter 302 transmits data over a noisy channel, in which some of the bits of data arrive corrupted at the receiver 304.

The output processor 306, in one embodiment, controls a packetizing process, including accessing data, encoding data, and modulating data for transmission. The transmission memory device 308 stores data that is transmitted by the transmitter 302. The data source 310 supplies a portion of data stored in the transmission memory device 308 to include in a packetized transmission packet.

In one embodiment, the LDPC encoder 312 encodes the portion of data supplied by the data source 310 according to an LDPC encoding scheme. In some embodiments, the LDPC encoder encodes a portion of data into a contiguous block of encoded data. The LDPC encoder generates the contiguous block of encoded data of a certain block size for a certain code rate. In some embodiments, the LDPC encoder 312 implements a convolutional LDPC code to encode the transmission packet. A convolutional code is a forward error-correction (FEC) scheme, in which the coded sequence is algorithmically achieved through the use of presently encoded data bits combined with previous encoded data bits from the same portion of data supplied by the data source 110.

In one embodiment, the block interleaver 314 interleaves the encoded data generated by the LDPC encoder 312. Interleaving is a method to protect the transmission against errors by arranging the bits in a non-contiguous order. In one embodiment, the modulator 316 implements an orthogonal frequency division multiple access modulation (OFDMA) scheme to modulate the transmission packet at the physical layer (PHY) and to drive the transmitter antenna 318 with the modulated transmission packet. In some embodiments, the transmitter modulates the transmission packet using Quadrature Phase Shift Keying (QPSK) or other similar modulation. The transmitter antenna 318 then transmits the modulated transmission packet signal to the receiver 304.

As depicted in FIG. 3, the receiver 304 includes at least one receiver antenna 320, a demodulator 322, a block de-interleaver 324, an LDPC decoder 326, an address generator 328, a data sink 330, a receiver memory device 332, and an input processor 334. The receiver 304 receives the modulated transmission packet signal from the transmitter 302 via the receiver antenna 320. When a transmission packet is sent across a noisy channel, portions of data in the transmission packet may be lost or corrupted, which may render at least some of the data contained in the transmission packet initially indecipherable by the receiver 304. There are numerous types of noise. One exemplary type of noise is fading. Fading refers to the distortion that a modulated signal experiences over certain propagation media. In wireless systems, fading is due to multipath propagation and is sometimes referred to as multipath induced fading. Other types of noise include frequency selectivity, interference, self interference, terrain blocking, nonlinearity, and dispersion.

The receiver antenna 320 receives the modulated transmission packet transmitted from the transmitter 302. The demodulator 322 senses the modulated transmission packet received by the antenna 320 and de-modulates the modulated transmission packet. In one embodiment, the demodulator 322 is an orthogonal demodulator configured to de-modulate an OFDMA modulated signal. In some embodiments, the demodulator 322 de-modulates a QPSK modulated signal or other similar modulated signal.

Following the demodulation of the modulated transmission packet, in one embodiment, the block de-interleaver 324 de-interleaves the block interleaved patterns applied to the transmission packet. For each block interleaving pattern there is a complementary block de-interleaving scheme.

Following the de-interleaving of the block interleaving patterns, the LDPC decoder 326 decodes each bit segment contained in the received code block according to an LDPC decoding process. As depicted, the LDPC decoder 326 includes a position designator 338, and a row designator 336. In some embodiments, the LDPC decoder 326 determines the cyclical shifting features among the rows and columns in a parity-check matrix. In some embodiments, the LDPC decoder 326 uses the address generator 328 to store, access, and update node information associated with the check nodes 202 and the variable nodes 204 of the LDPC decoding process. The data sink 330 then stores the decoded bits. Other embodiments may implement other types of decoders.

In one embodiment, the LDPC decoder 326 determines the cyclical shifting features among the rows and columns in a parity-check matrix and designates certain rows in the parity-check matrix as parent rows and other rows in the parity-check matrix as child rows. In the STiMi example using the ½ rate, the elements in a row are cyclically shifted 36 columns in the right direction every 18 rows, and the elements in a column are cyclically shifted 18 rows in the down direction every 36 column. For the ¾ rate, the elements in a row are cyclically shifted 72 columns in the right direction every 18 rows, and the elements in a column are cyclically shifted 18 rows in the down direction every 72 columns. Determining the cyclical shifting features among the rows and columns in a parity-check matrix allows node information storage to be addressed according to a row or a column.

An access address is used to access and update non-zero entries in the parity-check matrix. The access address is associated with the number of rows and columns corresponding to a non-zero element in the matrix. The total addresses accessed in LDPC decoding for the STiMi example are 4,608×6 rows+9,216×3 columns for the ½ rate and 2,304×12 rows+9,216×3 columns for the ¾ rate. In one embodiment, the addressing of node information associated with a parent non-zero element is generated with the table lookup (TLU) 344, which is described in more detail below. In the STiMi example, the table size is 108+216 for ½ rate and 216+432 for ¾ rate. The node information associated with a parent non-zero element is stored according to the actual position of the parent non-zero element. The node information associated with a child non-zero element is stored according to original position of a corresponding parent non-zero element. Storing the node information of a child non-zero element according to the original position of the corresponding parent non-zero element allows the addressing of node information associated with the child non-zero element to be generated by the modular adder 340 and/or the counter 342.

In some embodiments, the row designator 336 designates a row from a parity-check matrix as a parent row. The parent row includes an LDPC code word with a certain number of non-zero elements. In some embodiments, the row designator 336 designates other rows from the parity-check matrix as child rows. Each child row comprises a cyclically shifted version of the LDPC code word of the parent row. In some embodiments, the position designator 338 designates an original position order of each parent non-zero element of the parent row according to an actual position order of each parent non-zero element in the parent row. The actual position order is a numerical order of the parent non-zero elements from a first position at a leftmost parent non-zero element in an LDPC code word to a last position at a rightmost parent non-zero element in the LDPC code word. In some embodiments, the position designator 338 correlates a child non-zero element in a child row to the original position order of the parent non-zero element that corresponds to the child non-zero element.

The depicted address generator 328 includes at least one modular adder 340, and at least one counter 342. The depicted receiver memory device 332 includes a table lookup (TLU) 344. The LDPC decoder 326 implements the address generator 328 and the memory device 332 in the LDPC decoding process. In particular, the LDPC decoder 326 implements the TLU 344 to generate addressing information for a parent row of the parity-check matrix. In other words, in some embodiments, the TLU 344 provides access addresses only for the parent rows of the parity-check matrix. In some embodiments, the LDPC decoder 326 implements the modular adder 340 and the counter 342 to generate addressing information for a child row according to the address information generated by the TLU 344 for a parent row that corresponds to the child row.

In one embodiment, the depicted address generator 328 generates an address for an LDPC process of the LDPC decoder 326. In some embodiments, the modular adder 340 is implemented in software and/or hardware. In some embodiments, the modular adder 340 is an adder integrated-circuit (IC). In some embodiments, the address generator 328 uses at least one modular adder 340 to generate an address for an LDPC decoding process by the LDPC decoder 326. In some embodiments, the modular adder 340 generates an address associated with a child row of the parity-check matrix. In some embodiments, the LDPC decoder 326 uses the TLU 344 to generate an address of a parent row of the parity-check matrix and uses the modular adder 340 to generate an address of a child row according to the address generated by the TLU 344 for a corresponding parent row. In some embodiments, the LDPC decoder 326 uses the TLU 344 and the modular adder 340 in an initial procedure of the LDPC decoding process such as storing the initial node information of a parent non-zero element according to the actual position order of the parent non-zero element, and storing the initial node information of a child non-zero element according to the original position of the corresponding parent non-zero element.

In one embodiment, the counter 342 is implemented in software, firmware, hardware, or a combination thereof. In some embodiments, the counter 342 is a counter integrated-circuit (IC). In some embodiments, the address generator 328 uses at least one counter 342 to generate an address for an LDPC decoding process of the LDPC decoder 326. In some embodiments, the counter 342 generates an address associated with a child row of the parity-check matrix. In some embodiments, the LDPC decoder 326 uses the TLU 344 to generate an address of a parent row of the parity-check matrix and uses the counter 342 to generate an address of a child row according to the address generated by the TLU 344 for a corresponding parent row. In some embodiments, the LDPC decoder 326 uses the TLU 344 and the counter 342 in an updating procedure of the LDPC decoding process following the initial procedure. In some embodiments, the TLU 344 generates an offset to access and update the node information of a parent row. In some embodiments, the LDPC decoder 326 uses the counter 342 in conjunction with the offset generated by the TLU to access and update the node information of a child row.

In one embodiment, the LDPC decoder 326 finds the values of certain unknown or indecipherable variable nodes, bits of a data block that were corrupted during transmission from the transmitter 302 to the receiver 304. Using the STiMi Tanner graph of FIG. 2 as an example, to accomplish the task of recovering indecipherable bits, the STiMi variable nodes 204 and the STiMi check nodes 202 iteratively communicate with each other. From the STiMi check node 202 to the STiMi variable node 204, each STiMi check node 202 provides a particular STiMi variable node 204 with an estimate regarding the value of that particular STiMi variable node 204 based on the information coming from other adjacent STiMi variable nodes 204. From the STiMi variable node 204 to the STiMi check node 202 each STiMi variable node 204 relays to a connected STiMi check node 202 an estimate about its own value based on the feedback coming from other adjacent STiMi check nodes 202 based on the other edges connected to that STiMi variable node 204. For the case in which the STiMi variable node 204 has more than two STiMi check node connections, the STiMi variable node 204 performs a majority vote (soft decision) on the feedback coming from the other STiMi check node connections before reporting the decision to the STiMi check node 202 it is communicating with. In some embodiments, the above process is repeated until all STiMi variable nodes 204 are considered correct or until a predetermined maximum number of iterations are reached, and a decoding failure is declared.

In some embodiments, the memory devices 308 and 332 are random access memory (RAM) or another type of dynamic storage device. In other embodiments, the memory devices 308 and 332 are read-only memory (ROM) or another type of static storage device. In other embodiments, the illustrated memory devices 308 and 332 are representative of both RAM and static storage memory within the LDPC system 300. In some embodiments, the memory devices 308 and 332 are content-addressable memory (CAM). In other embodiments, the memory devices 308 and 332 are electronically programmable read-only memory (EPROM) or another type of storage device. Additionally, some embodiments store instructions as firmware such as embedded foundation code, basic input/output system (BIOS) code, LDPC decoding code, modular adder code, node information storage code, and other similar code.

In some embodiments, the receiver memory device 332 is configured to store a parity-check matrix associated with a received data block. In some embodiments, the receiver memory device 332 is configured to store node information associated with a parent row of the parity-check matrix. In some embodiments, the receiver memory device 332 is configured to store node information associated with a child row of the parity-check matrix. In some embodiments, the receiver memory device 332 is configured to store the node information associated with a child non-zero element according to the original position of the parent non-zero element that corresponds to the child non-zero element regardless of the actual position of the child non-zero element in the child row. In the case that the de-interleaving and LDPC decoding are successful, i.e., the de-interleaved and decoded bits are decipherable and no errors are detected, then the bits are stored in the receiver memory device 332 or transferred to upper layers (L2/L3) for further processing.

The input processor 334, in one embodiment, computes a calculation associated with the LDPC decoding process. In some embodiments, the processors 306 and 334 are central processing units (CPUs) with one or more processing cores. In other embodiments, the processors 306 and 334 are network processing units (NPUs) or another type of processing devices such as general purpose processors, application specific processors, multi-core processors, or microprocessors. Alternatively, at least one separate processor may be coupled to the LDPC decoder 326 and/or address generator 328. In general, the processors 306 and 334 execute one or more instructions to provide operational functionality to the transmitter 302 and receiver 304, respectively. The instructions may be stored locally in the processors 302 and 304 or in the memory devices 308 and 332. Alternatively, the instructions may be distributed across one or more devices such as the processors 306 and 334, the memory devices 308 and 332, or another data storage device.

FIG. 4 depicts a schematic block diagram of one embodiment of a variable node information storage scheme 400 for use with the LDPC decoder 326 of FIG. 3. The depicted variable node information storage scheme 400 includes a first row 402 of variable node memory blocks, a second row 404 of variable node memory blocks, through to a last row 406 of variable node memory blocks. In the STiMi example, there are six is per row of the parity-check matrix, and so there are six columns of memory blocks in the depicted variable node information storage scheme 400. Alternatively, some variable node information storage schemes have less or more columns of memory blocks. In some embodiments, the degree of parallel processing depends on the number of memory blocks implemented.

For the variable node updating procedure, 216 and 432 offset points are used for ½ and ¾ rate respectively. This is achieved with the TLU 344. In some embodiments, a parent row of a variable node is updated simultaneously. In order to achieve a relatively higher decoding speed, parallel processing may be implemented. Thus, variable node updating is performed simultaneously for every row in the H matrix. Thus, 12 and 24 check nodes may be accessed simultaneously for ½ and ¾ rate respectively, which can be obtained with 12 or 24 offset points generated by the TLU 344. For OPNS, the check node information required for its first child row can be accessed with offset points plus one, and the check node information required for the second child row can be accessed with offset points plus two. Thus, all of the check node information can be accessed and updated by using the counter 342, of which the offset point generated by the TLU 344 is the initial value. For example, when the variable information stored in the first cell of M0-Z is updated, the offset points are 256 of M0-Z and 0 of M6-Z. That is, the check node information stored in the 257^{th} cell of M0-Z and the 1^{st} cell of M6-Z is used to update the variable node stored in the 1^{st} cell of M0-Z. When the variable information stored in the second cell of M0-Z is updated, the check node information stored in the 258^{th} cell of M0-Z and the 2^{nd} cell of M6-Z is used to update the variable node stored in the 2^{nd} cell of M0-Z. That is, the accessing address is the offset point plus one. Thus, all of the variable node information updating can be performed by the counter 342, of which the offset point will be the initial value.

In some embodiments, each variable node memory block of the variable node information storage scheme 400 contains variable node information associated with the non-zero elements of two parent rows and the associated child rows of the two parent rows. For example, the first row of variable node memory blocks 402 contains the variable node information associated with the non-zero elements of the first and second parent rows and the child rows associated with the first and second parent rows. In the exemplary STiMi LDPC decoding process, there are 18 parent rows in the parity-check matrix. Thus, the variable node information storage scheme 400 from the STiMi example includes 9 rows of variable node memory blocks with two parent rows per row. The variable node information for each parent row and child row is stored according to the original position of the parent row's non-zero elements. For example, the first non-zero element of the first parent row, row 1 in the parity-check matrix, is stored in the Position 0 memory block of the first row 402 of variable node memory blocks. Thus, all first non-zero elements of each parent row are stored in Position 0, all second non-zero elements of each parent row are stored in Position 1, and so on, each non-zero element stored in the appropriate row of memory blocks. In the exemplary STiMi LDPC decoding process, there are 255 child rows that correspond to each of the 18 parent rows in the parity-check matrix, for a total of 4,608 total rows. Likewise, each non-zero element of a child row that corresponds to the first parent row is stored according to the position of the child non-zero element as it relates to the position of the parent non-zero element, the original position, not the actual position of the child non-zero element in the child row.

There are six non-zero elements per row of the STiMi parity-check matrix, thus there are six positions in the variable node information storage scheme 400 of FIG. 4. The order of the each set of parent non-zero elements are ordered 1-2-3-4-5-6 in the STiMi parity-check matrix, as each parent row is a unique version of an LDPC code word. Every set of 18 rows after the first 18 rows, the parent rows, are cyclically shifted versions of the 18 parent rows. Rows 19-36 are the first set of child rows, and so on. For example, the 19^{th} row in the STiMi parity-check matrix is the first child row, and corresponds to the first parent row, or 1^{st} row in the STiMi parity-check matrix. The actual positions of the child non-zero elements in the 19^{th} row may also be ordered 123456 like the parent rows. However, since the non-zero elements of a child row are a cyclically shifted version of the non-zero elements of a corresponding parent row, the order of the child non-zero elements as they relate to the original position of a corresponding parent row could be 1-2-3-4-5-6, 2-3-4-5-6-1, 3-4-5-6-1-2, 4-5-6-1-2-3, 5-6-1-2-3-4, or 6-1-2-3-4-5. For example, if the positions of the child non-zero elements of the 19^{th} row as they correspond to the 1^{st} row are 3-4-5-6-1-2, then the actual first child non-zero element of the 19^{th} row corresponds to the third non-zero element of the 1^{st} row, the actual second child non-zero element of the 19^{th} row corresponds to the fourth non-zero element of the 1^{st} row, and so on. Thus, the first child non-zero element of the 19^{th} row is stored in position 2 of the first row 402 of variable node memory blocks, the second child non-zero element of the 19^{th} row is stored in position 3 of the first row of variable node memory blocks 402, and so on.

In one embodiment, there are 54 memory blocks in the variable node information storage scheme 400, 6 memory blocks per row, and 9 rows. Each memory block includes 512 memory cells, cell-0 through cell-511. Alternatively, the variable node information storage scheme 400 includes less or more memory blocks with less or more memory cells per memory block.

In one embodiment, the node information associated with the first non-zero element of the 1^{st} parent row of the parity-check matrix is stored in the first cell, cell-o, of the first memory block column, Position 0, in the first row 402 of variable node memory blocks. The node information associated with the second non-zero element of the 1^{st} parent row of the parity-check matrix is stored in the first cell, cell-0, of the second memory block column, Position 1, in the first row 402 of variable node memory blocks, and so on. The node information associated with the child non-zero element of the 19^{th} row that corresponds to the first parent non-zero element of the first parent row is stored in the second cell, cell-1, of the first memory block column, Position 0, in the first row 402 of the variable node memory blocks. The node information associated with the child non-zero element of the 19^{th} row that corresponds to the second parent non-zero element of the first parent row is stored in the second cell, cell-1, of the second memory block column, Position 1, in the first row 402 of the variable node memory blocks, and so on. The node information associated with the child non-zero element of the 37^{th} row that corresponds to the first parent non-zero element of the first parent row is stored in the third cell, cell-2, of the first memory block column, Position 0, in the first row 402 of the variable node memory blocks. The node information associated with the child non-zero element of the 37^{th} row that corresponds to the second parent non-zero element of the first parent row is stored in the third cell, cell-2, of the second memory block column, Position 1, in the first row 402 of the variable node memory blocks, and so on.

Furthermore, the node information associated with the first non-zero element of the 2^{nd} parent row of the parity-check matrix is stored in the two hundred fifty seventh cell, cell-256, of the first memory block column, Position 0, in the first row 402 of the variable node memory blocks. The node information associated with the second non-zero element of the 2^{nd} parent row of the parity-check matrix is stored in the two hundred fifty seventh cell, cell-256, of the second memory block column, Position 1, in the first row 402 of the variable node memory blocks, and so on. In other words, the variable node information associated with the first non-zero element of the 1^{st} parent row and every child non-zero element that corresponds to a cyclical shifted version of the first non-zero element of the 1^{st} parent row are stored, in respective row order, in the first 256 cells of the first memory block column, Position 0, in the first row 402 of the variable node memory blocks. The node information associated with the second non-zero element of the 1^{st} parent row and every child non-zero element that corresponds to a cyclical shifted version of the second non-zero element of the 1^{st} parent row are stored, in respective row order, in the first 256 cells of the second memory block column, Position 1, in the first row 402 of the variable node memory blocks, and so on.

Storing and accessing node information for a parity-check matrix may include thousands or tens of thousands of storage and accessing routines to the receiver memory device 332 per iteration of the LDPC decoding process. Storing the node information associated with a particular non-zero element of a parent row in consecutive cells of a single memory block according to the original position of the non-zero element in the respective parent row allows the address generator 328 to generate an address for the LDPC decoding process with the modular adder 340 and/or counter 342. In some embodiments, the receiver memory device 332 includes the variable node memory blocks of the variable node information storage scheme 400. Alternatively, the variable node memory blocks of the variable node information storage scheme 400 are included in a separate and/or dedicated memory device. In some embodiments, the variable node memory blocks of the variable node information storage scheme 400 are distributed over several dedicated memory devices.

FIG. 5 depicts a schematic block diagram of one embodiment of a check node information storage scheme 500 for use with the LDPC decoder 326 of FIG. 3. The depicted check node information storage scheme 500 includes a first row 502 of check node memory blocks, a second row 504 of check node memory blocks, through to a last row 506 of check node memory blocks.

In the STiMi example, there are 6 ones per row of the parity-check matrix, and so there are six columns of memory block in the depicted STiMi check node information storage scheme 500. Alternatively, some variable node information storage schemes have less or more columns of memory blocks.

In some embodiments, the storage routine of the check node information storage scheme 500 is substantially similar to the storage routine of the variable node information storage scheme 400 with reference to FIG. 4. In other words, the check node information associated with the first non-zero element of the 1^{st} parent row and every child non-zero element that corresponds to a cyclical shifted version of the first non-zero element of the 1^{st} parent row are stored, in respective row order, in the first 256 cells of the first memory block column, Position 0, in the first row 502 of check node memory blocks. The node information associated with the second non-zero element of the 1^{st} parent row and every child non-zero element that corresponds to a cyclical shifted version of the second non-zero element of the 1^{st} parent row are stored, in respective row order, in the first 256 cells of the second memory block column, Position 1, in the first row 502 of check node memory blocks, and so on.

For the check node updating procedure, a check node receives variable node information and updates the check node information row by row. For example, the variable node information stored in the first cell of the memory blocks in FIG. 4 is read and processed in a check node to generate updated check node information stored in the cells of the check node information memory blocks of FIG. 5. Thus, in some embodiments, the counter 342 generates an access address for the check node updating procedure.

In some embodiments, each check node memory block of the check node information storage scheme 500 contains check node information associated with the non-zero elements of two parent rows and the associated child rows of the two parent rows. For example, the first row 502 of check node memory blocks contains the check node information associated with the non-zero elements of the first and second parent rows and the child rows associated with the first and second parent rows. In the exemplary STiMi LDPC decoding process, there are 18 parent rows in the parity-check matrix. Thus, the check node information storage scheme 500 of FIG. 5 includes 9 rows of check node memory blocks with two parent rows per row of check node memory blocks. In some embodiments, the check node information storage scheme 500 includes 54 memory blocks with 512 memory cells, cell-0 through cell-511, per memory block. Alternatively, the check node information storage scheme 500 includes less or more memory blocks with less or more memory cells per memory block.

In some embodiments, the receiver memory device 332 includes the check node memory blocks of the check node information storage scheme 500. Alternatively, the check node memory blocks of the check node information storage scheme 500 are included in a separate and/or dedicated memory device. In some embodiments, the check node memory blocks of the check node information storage scheme 500 are distributed over several dedicated memory devices.

Out of the total 4,608 rows in the STiMi parity-check matrix, the first 18 rows of are designated as parent rows. The subsequent rows in the parity-check matrix are designated as children rows, or child rows. Each child row is the cyclically shifted version of one of the parent rows. In the STiMi example, each parent row correlates to 255 child rows. Furthermore, each non-zero element of a certain child row, or child non-zero element, correlates with a parent non-zero element of a correlated parent row. The actual position of each parent non-zero element such as first, second, third, fourth, fifth, or sixth position is referred to as the original position. The node information relating to a parent non-zero element is stored according to the detected actual position of each parent non-zero element. Likewise, the node information relating to a child non-zero element is stored according to the original position order of the correlated parent non-zero element, regardless of the actual position order of the child non-zero element in a child row of the parity-check matrix. In other words, the first parent non-zero element of a particular parent row correlates to one of the child non-zero elements of a particular child row. However, the child non-zero element that correlates to the first parent non-zero element may be in any order on the child row such as the third non-zero element of the particular child row. Even though the actual position of the correlated child non-zero element may be the third position, the third child non-zero element of a child row is stored in the first position memory block when it correlates with the parent non-zero element that is in the first position, or whose original position is the first position.

The node information, including variable nodes 204 and check nodes 202, are stored and updated in the row order. During the initial procedure of the LDPC decoding process of the STiMi example, 108 and 216 column numbers for the parent rows, the accessing addresses, are obtained from the TLU 344 for ½ and ¾ rate respectively, while the accessing address for children rows are generated with the modular adder 340. For the check node updating procedure, the check node information is updated row by row based on variable node information passed by a variable node 204. For the STiMi variable node updating procedure, 216 and 432 offset points are generated by the TLU 344 and used for ½ and ¾ rate, respectively. In one embodiment, a parent row of the variable node 204 is updated simultaneously. Thus, information from 12 and 24 check nodes 202 is used for ½ and ¾ rate respectively, which can be obtained with 12 or 24 offset points generated by the TLU 344. For OPNS, the check node information for the first child row is accessed with offset points plus one, and the check node information for the second child row is accessed with offset points plus two, and so on. Thus, the variable information is obtained by the counter 342, for which the offset point is the initial value.

FIG. 6 depicts a schematic flow chart diagram of one embodiment of an original position node information storage (OPNS) method 600 for use with the modular adder 340 of FIG. 3. Although the OPNS method 600 is described in conjunction with the modular adder 340 of FIG. 3, some embodiments of the OPNS method 600 may be implemented with other types of modular adders. At block 602, the LDPC decoder 326 determines the cyclical shifting features among the rows and columns in a parity-check matrix. Each row includes an LDPC code of a certain code length. In some embodiments, the receiver 304 designates a set of rows in the parity-check matrix as parent rows. The parent rows contain a set of unique LDPC codes associated with a certain LDPC encoding scheme. Following the parent rows, the LDPC codes are repeated in sets as cyclically shifted versions of the prior set. In the exemplary STiMi system there are 18 unique LDPC codes and each row is an LDPC code with a length of 9,216 bits. The first 18 rows of the parity-check matrix are the parent rows, the first set of LDPC codes, and each set of LDPC codes subsequent to the parent rows are then designated as child rows.

At block 604, the OPNS position designator 338 determines an actual position of a parent non-zero element in the parity-check matrix and designates the actual position of the parent non-zero element as an original position of the parent non-zero element.

At block 606, the row designator 336 correlates each child row with a parent row. The row designator 336 also correlates a child non-zero element with the original position of the corresponding parent non-zero element of the correlated parent row. In other words, using the STiMi example, the actual order of the positions of the six non-zero elements of the 1^{st} row in the STiMi parity-check matrix, the first parent row, are designated as original positions 1-2-3-4-5-6. Likewise, the non-zero elements of each row of the first 18 rows of the parity-check matrix are designated as original positions 1-2-3-4-5-6. However, regardless of the actual order of the positions of the six non-zero elements of each child row, each child non-zero element is correlated with a corresponding parent non-zero element.

At block 608, the LDPC decoder 326 stores node information associated with a parent non-zero element according to the original position of the parent non-zero element. Storing the parent node information according to the original position of the parent non-zero elements allows the LDPC decoder 326 to access and update the parent node information via the TLU 344.

At block 610, the LDPC decoder 326 stores node information associated with the child non-zero element according to the original position of the correlated parent non-zero element. Storing the child node information according to the original position of the correlated parent non-zero elements allows the LDPC decoder 326 to access and update the child node information via the modular adder 340. At block 612, the LDPC decoder 326 uses the counter 342 to generate an access address associated with stored node information of an LDPC decoding process according to an offset generated by the TLU 344.

In one embodiment, the OPNS method 600 is implemented for the BP algorithm. In some embodiments, a BP-based algorithm is implemented. Modifications of the BP-based algorithm such as the offset BP-based algorithm and the normalized BP-based algorithm may be used in order to approach the performance of the BP algorithm. In some embodiments, the OPNS method 600 is implemented with the BP-based, the Log-BP, the Log-BP-based, the normalized BP-based, the offset BP-based and/or other variations of the belief propagation algorithm. In some embodiments, the OPNS method 600 is implemented with an LDPC decoder 326 designed to operate in a serial mode. In some embodiments, the OPNS method 600 is implemented with an LDPC decoder 326 designed to operate in a parallel mode. Embodiments of the OPNS method 600 reduce the memory requirements of an LDPC decoding process. Furthermore, embodiments of the OPNS method 600 reduce the complexity of the address generator 328 based on the structure and properties of the LDPC code compared with conventional techniques.

It should also be noted that at least some of the operations for the methods may be implemented using software instructions stored on a computer useable storage medium for execution by a computer. As an example, an embodiment of a computer program product includes a computer useable storage medium to store a computer readable program that, when executed on a computer, causes the computer to perform operations, including an operation to access and update node information associated with a parent row of the parity-check matrix via the TLU 344, an operation to access and update node information associated with a child row of the parity-check matrix via the modular adder 344, and an operation to store node information associated with a child non-zero element according to the original position of the parent non-zero element that corresponds to the child non-zero element. As described above, an access address used for node information updating can be generated with the counter 342 in the OPNS method 600. The modular adder 340 and the counter 342 consume less silicon than the TLU 344. In OPNS, only the parent rows are generated with the TLU 344. Generating only the parent addresses with the TLU 344 reduces the size of the TLU 344, and generating the child addresses with the modular adder 340 and/or counter 342 consumes less silicon than generating addresses only with the TLU 344. The complexity of the storage and memory access processes of the iterative LDPC decoding procedure is simplified and memory access times are reduced, substantially minimizing the processing time of an LDPC process.

Embodiments of the invention can take the form of an entirely hardware embodiment, an entirely software embodiment, or an embodiment containing both hardware and software elements. In one embodiment, the invention is implemented in software, which includes but is not limited to firmware, resident software, microcode, etc.

Furthermore, embodiments of the invention can take the form of a computer program product accessible from a computer-usable or computer-readable storage medium providing program code for use by or in connection with a computer or any instruction execution system. For the purposes of this description, a computer-usable or computer readable storage medium can be any apparatus that can store the program for use by or in connection with the instruction execution system, apparatus, or device.

The computer-useable or computer-readable storage medium can be an electronic, magnetic, optical, electromagnetic, infrared, or semiconductor system (or apparatus or device), or a propagation medium. Examples of a computer-readable storage medium include a semiconductor or solid state memory, magnetic tape, a removable computer diskette, a random access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

An embodiment of a data processing system suitable for storing and/or executing program code includes at least one processor coupled directly or indirectly to memory elements through a system bus such as a data, address, and/or control bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Additionally, network adapters also may be coupled to the system to enable the data processing system to become coupled to other data processing systems or remote printers or storage devices through intervening private or public networks. Modems, cable modems, and Ethernet cards are just a few of the currently available types of network adapters.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A receiver to receive a signal associated with a low-density parity-check (LDPC) code, the receiver comprising:
a memory device to store data related to an LDPC decoding process;
an address generator coupled to the memory device, the address generator to generate an access address to the stored data; and
an LDPC decoder coupled to the address generator, the LDPC decoder to perform the LDPC decoding process, wherein the LDPC decoder comprises:
a row designator to designate a row from a parity-check matrix as a parent row and to designate a plurality of corresponding rows from the parity-check matrix as child rows; and
a position designator coupled to the row designator, the position designator to designate an original position order of each parent non-zero element of the parent row according to an actual position order of each parent non-zero element in the parent row, wherein the actual position order comprises a numerical order of the parent non-zero elements.

2. The receiver of claim 1, wherein the position designator is further configured to correlate each child non-zero element to the original position order of a corresponding parent non-zero element.

3. The receiver of claim 1, wherein the memory device is further configured to store data associated with each parent non-zero element according to the original position order of the parent non-zero elements in the parent row.

4. The receiver of claim 1, wherein the memory device is further configured to store data associated with each child non-zero element according to the original position order of the corresponding parent non-zero element.

5. The receiver of claim 4, wherein the memory device further comprises a table lookup (TLU) coupled to the LDPC decoder, the TLU to generate a parent access address to the parent node information of each parent non-zero element, wherein the parent access address comprises:
a column access address associated with a column of the parent row; and
an offset access address, wherein the TLU is configured to generate an offset according to the number of child rows associated with the parent row.

6. The receiver of claim 5, wherein the address generator is further configured to generate a child access address to the data associated with each child non-zero element, wherein the child access address is based on the parent access address generated by the TLU.

7. The receiver of claim 6, wherein the address generator further comprises a modular adder coupled to the LDPC decoder, the modular adder to generate the child access address based on the column access address.

8. The receiver of claim 6, wherein the address generator further comprises a counter coupled to the LDPC decoder, the counter to generate the child access address based on the offset, wherein a first child row access address is generated by the offset plus one and an Nth child row access address is generated by the offset plus N.

9. An LDPC decoding method comprising:
storing data related to an LDPC decoding process;
generating an access address to the stored data;
designating a row from a parity-check matrix as a parent row and to designate a plurality of corresponding rows from the parity-check matrix as child rows; and
designating an original position order of each parent non-zero element of the parent row according to an actual position order of each parent non-zero element in the parent row, wherein the actual position order comprises a numerical order of the parent non-zero elements.

10. The LDPC decoding method of claim 9, further comprising correlating each child non-zero element to the original position order of a corresponding parent non-zero element.

11. The LDPC decoding method of claim 9, further comprising storing data associated with each parent non-zero element according to the original position order of the parent non-zero elements in the parent row.

12. The LDPC decoding method of claim 9, further comprising storing data associated with each child non-zero element according to the original position order of the corresponding parent non-zero element.

13. The LDPC decoding method of claim 12, further comprising generating a parent access address to the parent node information of each parent non-zero element, wherein generating the parent access address further comprises:
generating a column access address associated with a column of the parent row; and
generating an offset access address associated with an offset generated by a table lookup, wherein the offset is generated according to the number of child rows associated with the parent row.

14. The LDPC decoding method of claim 13, further comprising generating a child access address to the data associated with each child non-zero element, wherein the child access address is based on the parent access address generated by the table lookup.

15. The LDPC decoding method of claim 14, further comprising generating the child access address based on the column access address.

16. The LDPC decoding method of claim 14, further comprising generating the child access address based on the offset, wherein a first child row access address is generated by the offset plus one and an Nth child row access address is generated by the offset plus N.

17. A computer program product comprising a computer useable storage medium to store a computer readable program that, when executed on a computer, causes the computer to perform operations comprising:
store data related to an LDPC decoding process;
generate an access address to the stored data;
designate a row from a parity-check matrix as a parent row and to designate a plurality of corresponding rows from the parity-check matrix as child rows; and
designate an original position order of each parent non-zero element of the parent row according to an actual position order of each parent non-zero element in the parent row, wherein the actual position order comprises a numerical order of the parent non-zero elements.

18. The computer program product of claim 17, wherein the computer readable program, when executed on the computer, causes the computer to perform operations to correlate each child non-zero element to the original position order of a corresponding parent non-zero element.

19. The computer program product of claim 17, wherein the computer readable program, when executed on the computer, causes the computer to perform operations comprising:
store data associated with each parent non-zero element according to the original position order of the parent non-zero elements in the parent row; and
store data associated with each child non-zero element according to the original position order of the corresponding parent non-zero element.

20. The computer program product of claim 19, wherein the computer readable program, when executed on the computer, causes the computer to perform operations comprising:
generate a column access address associated with a column of the parent row;
generate an offset access address associated with an offset generated by a table lookup, wherein the offset is generated according to the number of child rows associated with the parent row;
generate a child access address based on the column access address; and
generate the child access address based on the offset, wherein a first child row access address is generated by the offset plus one and an Nth child row access address is generated by the offset plus N.
